(19) United States
(12) Patent Application Publication
(10) Pub. No.: US 2026/0033296 A1
(43) Pub. Date: Jan. 29, 2026

(54) Inspection Pattern and Semiconductor Integrated Circuit Therewith

(71) Applicant: Nippon Telegraph and Telephone Corporation, Tokyo (JP)

(72) Inventors: Masayuki Takahashi, Musashino-shi, Tokyo (JP); Yusuke Nasu, Musashino-shi, Tokyo (JP); Yuichiro Ikuma, Musashino-shi, Tokyo (JP); Ken Tsuzuki, Musashino-shi, Tokyo (JP); Yosuke Hinakura, Musashino-shi, Tokyo (JP)

(21) Appl. No.: 18/993,106

(22) PCT Filed: Jul. 27, 2022
(86) PCT No.: PCT/JP2022/028926

§ 371 Date: Jan. 10, 2025

(51) Int. Cl. H01L 21/66; G02F 1/21; G02F 1/225; H01L 23/00

(52) U.S. Cl. CPC H01L 22/32; H01L 24/05; H01L 24/13; G02F 1/212; G02F 1/225; H01L 2224/05647; H01L 2224/13147

(57) ABSTRACT

An inspection pattern capable of performing wafer-level automatic inspection using a cantilever-type probe card is provided. An inspection pattern according to one embodiment of the present disclosure includes: a Cu pillar pad formed on a semiconductor substrate; a Cu pillar formed on the Cu pillar pad; and an inspection pad formed on the semiconductor substrate, electrically coupled adjacent to or proximate to the Cu pillar pad, and configured to provide a region that a cantilever-type probe comes in contact with during wafer-level automatic inspection.

### TECHNICAL FIELD

The present disclosure relates to an inspection pattern and a semiconductor integrated circuit including the inspection pattern.

### BACKGROUND ART

Conventionally, Cu pillars (copper pillars) used for flip-chip connection between a semiconductor integrated circuit chip and a semiconductor package substrate are known (see, for example, Non Patent Literatures 1 and 2). A Cu pillar (copper pillar) is a technique for forming a pillar (pillar) of Cu on an aluminum electrode pad of the semiconductor integrated circuit chip, and enables a narrower pad pitch and terminal densification.

Semiconductor integrated circuits used in optical communication modules and optical devices include semiconductor integrated circuits including optical circuits (hereinafter also referred to as optical semiconductor integrated circuit chips). In recent years, also in the optical semiconductor integrated circuit chips, the terminal densification and the narrower pad pitch are required in order to cope with an increase in transmission capacity, a wider bandwidth, and densification of optical communication, and the Cu pillar techniques have been used.

The degree of integration of components of the optical communication module increases due to the demand for the increase in transmission capacity. To improve a product yield, it is necessary to select non-defective chips by wafer-level automatic inspection of the optical semiconductor integrated circuit chip included in the optical communication module. In the wafer-level automatic inspection, inspection using an optical input/output probe and an electric probe at the same time is performed in order to perform optical measurement and electrical measurement.

For the wafer-level automatic inspection of the semiconductor integrated circuit, a vertical-type probe card is commercially available, which performs inspection by vertically contacting with a Cu pillar without being provided with a pad (see, for example, Non Patent Literature 3).

### CITATION LIST

### Non Patent Literature

Non Patent Literature 1: B. Tunaboylu, “Testing of Copper Pillar Bumps for Wafer Sort,” in IEEE Transactions on Components, Packaging and Manufacturing Technology, vol. 2, no. 6, pp. 985-993, June 2012, doi: 10.1109/TCPMT.2011.2173493

Non Patent Literature 2: Shinko Electric Industries Co., Ltd., “Cu pillar”, [online], Shinko Electric Industries Co., Ltd. homepage, [searched on Jul. 12, 2022], Internet (URL: https://www.shinko.co.jp/product/package/assembly/cu-pillar.php)

Non Patent Literature 3: Seiken Co., Ltd., “Probe card (suichoku-gata, cantilever-gata) no tokucho, hikaku (in Japanese) (Characteristics and Comparison of Probe Card (Vertical Type and Cantilever Type))” [online], Seiken Co., Ltd. homepage, [searched on Jul. 12, 2022], Internet (URL: https://www.seiken.co.jp/semiconductor/probecard.html)

### SUMMARY OF INVENTION

In the wafer-level automatic inspection of a wafer on which a semiconductor integrated circuit including a Cu pillar is formed (hereinafter, the waver is referred to as a semiconductor integrated circuit wafer), it is common to use a vertical-type probe card that has a small dent and hardly damages the Cu pillar.

On the other hand, in the wafer-level automatic inspection of a wafer on which an optical semiconductor integrated circuit included in an optical communication device is formed (hereinafter, the wafer is referred to as an optical semiconductor integrated circuit wafer), inspection using an optical input/output probe and an electric probe at the same time is required to perform optical measurement and electrical measurement. However, in the case of the vertical-type probe card, it is not possible to provide a region where the optical input/output probe is brought into contact with the optical semiconductor integrated circuit wafer due to its structure, and there is a problem that the wafer-level automatic inspection for the optical semiconductor integrated circuit chip cannot be performed.

Therefore, in the wafer-level automatic inspection for the optical semiconductor integrated circuit chip, a cantilever-type probe card can be used, which can secure a region for contacting the optical input/output probe with the wafer by forming the probe card into a rectangular shape or a U-shape. However, the cantilever-type probe card generally has a large contact mark, and there is a problem that measurement cannot be performed by directly bringing the card into contact with the Cu pillar.

The present disclosure has been made in view of such problems, and an object thereof is to provide an inspection pattern and a semiconductor integrated circuit capable of wafer-level automatic inspection using a cantilever-type probe card without bringing a probe into contact with a Cu pillar.

To achieve such an object, an inspection pattern according to one embodiment of the present disclosure includes: a Cu pillar pad formed on a semiconductor substrate; a Cu pillar formed on the Cu pillar pad; and an inspection pad formed on the semiconductor substrate, electrically coupled adjacent to or proximate to the Cu pillar pad, and configured to provide a region that a cantilever-type probe comes in contact with during wafer-level automatic inspection.

According to the inspection pattern of an embodiment of the present disclosure, it is possible to perform wafer-level automatic inspection without bringing the probe of the probe of the cantilever-type probe card into contact with the Cu pillar.

### BRIEF DESCRIPTION OF DRAWINGS

FIG. 1 is views for describing a Cu pillar, in which FIG. 1(a) is a top view and FIG. 1(b) is a side view.

FIG. 2 is views illustrating a pattern for inspection according to an embodiment of the present disclosure, in which FIG. 2(a) is a top view and FIG. 2(b) is a side view.

FIG. 3 is a view illustrating a schematic configuration of an optical semiconductor integrated circuit according to an embodiment of the present disclosure.

FIG. 4 is a view for describing a state in which a chip having a Cu pillar according to an embodiment of the present disclosure is mounted on an external package substrate or circuit substrate.

FIG. 5 is a view for describing a state in which a chip having a Cu pillar is mounted on an external package substrate or circuit substrate.

FIG. 6 is a view illustrating a schematic configuration of an optical semiconductor integrated circuit according to an embodiment of the present disclosure.

FIG. 7 is views illustrating a cantilever-type probe card and a chip during wafer-level automatic inspection, in which FIG. 7(a) is a top view and FIG. 7(b) is a side view.

FIG. 8 is views illustrating states in which a needle tip of a cantilever-type probe is in contact with an inspection pad 20, in which FIG. 8(a) is a view illustrating the cantilever-type probe in which the needle tip is less (newer) scraped and FIG. 8(b) is a view illustrating the cantilever-type probe in which the needle tip is more scraped.

FIG. 9 is a view illustrating a schematic configuration of an optical semiconductor integrated circuit according to an embodiment of the present disclosure.

FIG. 10 is a view illustrating a schematic configuration of an optical semiconductor integrated circuit according to an embodiment of the present disclosure.

FIG. 11 is a view illustrating a schematic configuration of an optical semiconductor integrated circuit according to an embodiment of the present disclosure.

### DESCRIPTION OF EMBODIMENTS

Hereinafter, an optical semiconductor integrated circuit according to embodiments of the present disclosure will be described in detail with reference to the drawings. The same or similar reference numerals denote the same or similar components, and repetitive description may be omitted in some cases. Although the optical semiconductor integrated circuit is an integrated circuit including an optical circuit, the present disclosure can be described using a semiconductor integrated circuit not including an optical circuit instead of the optical semiconductor integrated circuit.

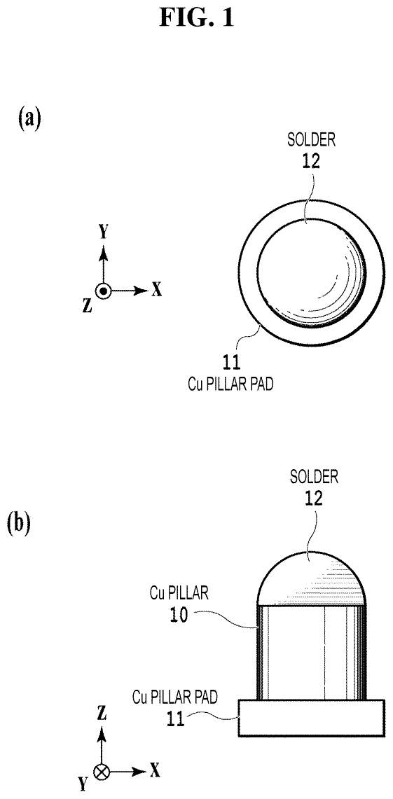

FIG. 1 is views for describing a Cu pillar, in which FIG. 1(a) is a top view and FIG. 1(b) is a side view. The optical semiconductor integrated circuit including an optical circuit according to an embodiment of the present disclosure can also achieve terminal densification and narrower pad pitch using the Cu pillar. As illustrated in FIG. 1, a Cu pillar 10 is formed on a Cu pillar pad 11. The

Cu pillar 10 has a columnar shape, and has a circular cross section in a horizontal direction (XY plane direction). The Cu pillar pad 11 also has a columnar shape, and a diameter of a cross section in the horizontal direction is larger than a diameter of the Cu pillar 10. Solder 12 is arranged on an upper surface of the Cu pillar 10. In top view, the Cu pillar 10 is located inside the Cu pillar pad 11. The solder 12 on the upper surface of the Cu pillar 10 forms a bump.

### First Embodiment

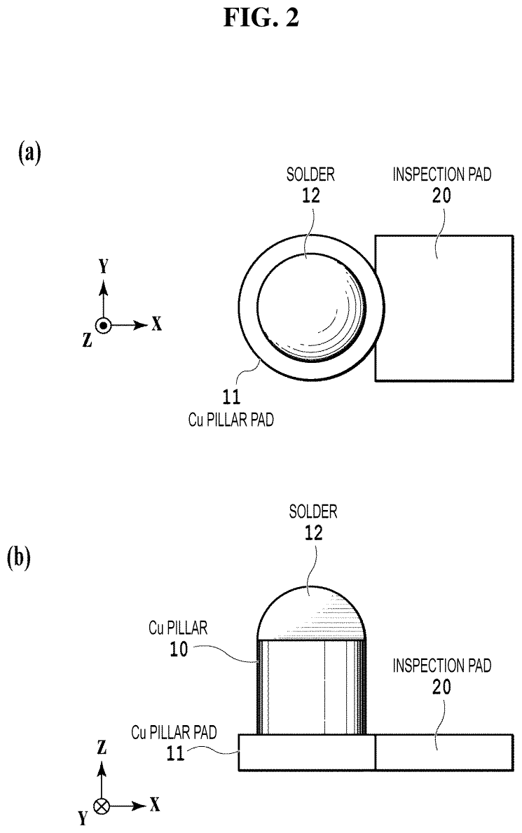

A pattern for inspection according to the first embodiment of the present disclosure will be described with reference to FIG. 2. FIG. 2 is views illustrating a pattern for inspection, in which FIG. 2(a) is a top view and FIG. 2(b) is a side view. The pattern for inspection illustrated in FIG. 2 is formed in the optical semiconductor integrated circuit on a wafer, and is used in wafer-level automatic inspection of the optical semiconductor integrated circuit.

As illustrated in FIG. 2, the pattern for inspection includes the Cu pillar pad 11, the Cu pillar 10 arranged on the Cu pillar pad 11, and an inspection pad 20 having an overlap with the Cu pillar pad 11. The inspection pad 20 provides a region that a cantilever-type probe arranged on a cantilever-type probe card comes in contact with during the wafer-level automatic inspection. It is sufficient that the Cu pillar pad 11 and the inspection pad 20 are arranged adjacent to each other, and the Cu pillar pad 11 and the inspection pad 20 do not need to have an overlapping region in a Z-axis direction.

For example, in a case where the inspection pad 20 is formed using Cu as a material, the Cu pillar pad 11 and the inspection pad 20 can be formed as one continuous region by a same manufacturing process.

FIG. 2 also illustrates the solder 12 on the upper surface of the Cu pillar 10. The solder 12 constitutes a bump in flip-chip connection.

According to the pattern for inspection (in the present specification, also simply referred to as an inspection pattern) of the present embodiment, it is not necessary to bring the cantilever-type probe into contact with the Cu pillar 10, the Cu pillar pad 11, and the solder 12 at the time of wafer-level automatic inspection. Therefore, contact marks are not generated in the Cu pillar 10, the Cu pillar pad 11, and the solder 12.

As described above, by providing the inspection pattern including the inspection pad on the optical semiconductor integrated circuit wafer, it becomes possible to perform the wafer-level automatic inspection using the cantilever-type probe card. Note that the present embodiment is applicable not only to an optical semiconductor integrated circuit wafer but also to a semiconductor integrated circuit wafer not including an optical circuit. That is, by providing the inspection pattern including the inspection pad on the semiconductor integrated circuit wafer, it becomes possible to perform the wafer-level automatic inspection using the cantilever-type probe card. By using a cantilever-type probe card that is lower in cost than a vertical-type probe card, it is possible to perform the wafer-level automatic inspection with lower inspection cost.

### Second Embodiment

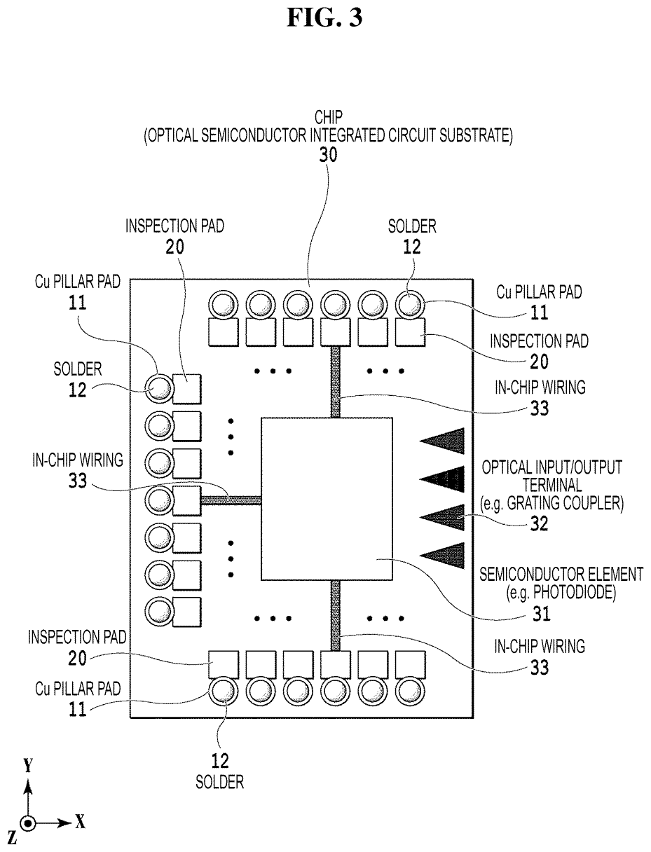

An optical semiconductor integrated circuit according to a second embodiment of the present disclosure will be described with reference to FIGS. 3, 4, and 5. FIG. 3 illustrates one of a plurality of optical semiconductor integrated circuits formed on a wafer. The optical semiconductor integrated circuit is an integrated circuit including an optical circuit, and is formed on the wafer. As described above, the optical semiconductor integrated circuit is cut out as a chip including one optical semiconductor integrated circuit from the wafer after wafer-level automatic inspection. The chip cut out from the wafer is modularized together with other components to constitute an optical communication module.

The optical semiconductor integrated circuit illustrated in FIG. 3 includes a rectangular chip 30 (that is, an optical semiconductor integrated circuit substrate), an optical input/output terminal 32 and a semiconductor element 31 formed on a principal plane (XY plane) of the chip 30, a plurality of inspection patterns, and in-chip wiring 33 electrically connecting each of the plurality of inspection patterns and the semiconductor element 31.

Each of the plurality of inspection patterns formed on the chip 30 includes an inspection pattern described with reference to FIG. 2, that is, a Cu pillar pad 11, a Cu pillar 10, an inspection pad 20, and solder 12. The inspection pad 20 arranged adjacent to the Cu pillar pad 11 is electrically connected to the semiconductor element 31 by the in-chip wiring 33. The inspection pad 20 provides a region that a cantilever-type probe arranged on a cantilever-type probe card comes in contact with during the wafer-level automatic inspection performed before the chip 30 is cut out from the wafer. The Cu pillar pad 11, the Cu pillar 10, and the solder 12 provide a connection point for flipping the chip 30 with one or more of a driver IC, a bias circuit, a transimpedance amplifier (TIA), and other elements (not illustrated) such as a wiring board and a radio frequency (RF) wiring board of the semiconductor element 31, for example.

As illustrated in FIG. 3, a plurality of the inspection patterns is linearly arranged near an end surface of the rectangular chip 30, that is, near an outer periphery of the chip 30. The Cu pillar pad 11 of each inspection pattern is arranged at a position closer to the end surface than the inspection pad 20. Further, the inspection pad 20 of each inspection pattern is arranged at a position in a direction away from the end surface closest to the Cu pillar pad 11 (a direction toward the end surface facing the closest end surface). The Cu pillar 10 is arranged on the Cu pillar pad 11, and the solder 12 is arranged on an upper surface of the Cu pillar 10. In FIG. 3, the Cu pillar 10 is located below the solder 12.

The optical input/output terminal 32 is, for example, a grating coupler, and is an optical circuit integrated on the chip 30. The semiconductor element 31 is, for example, a photodiode, and is an optical circuit integrated on the chip 30.

In the case where the semiconductor element 31 of the chip 30 of the present embodiment is a photodiode, the photodiode of the chip 30 in the optical communication module is biased from an external bias source via the Cu pillar 10, photoelectrically converts light from another optical circuit, the light being incident via the grating coupler, and operates to supply an electrical signal to the external TIA via the Cu pillar 10. Meanwhile, in the wafer-level automatic inspection, the photodiode of the chip 30 is biased from the inspection device through the cantilever-type probe in contact with the inspection pad 20, photoelectrically converts light from an optical probe, the light being incident via the grating coupler, and operates to supply an electrical signal to the inspection device via the cantilever-type probe in contact with the inspection pad 20.

In the case where the semiconductor element 31 of the chip 30 of the present embodiment is a laser diode, the laser diode of the chip 30 is supplied with a control signal from an external driver IC (or an RF wiring board connected to the external driver IC) via the Cu pillar 10, and operates to emit an optical signal to another optical circuit via the grating coupler in the optical communication module. Meanwhile, in the wafer-level automatic inspection, the laser diode of the chip 30 is supplied with the control signal from the inspection device via the cantilever-type probe in contact with the inspection pad 20, and operates to supply the optical signal from the optical probe to the inspection device via the grating coupler.

In the case where the semiconductor element 31 of the chip 30 of the present embodiment is an optical modulator, the optical modulator of the chip 30 is supplied with a modulation signal from an external driver IC (or an RF wiring board connected to the external driver IC) via the Cu pillar 10, modulates an optical signal from another optical circuit, the optical signal being incident via a part of the grating coupler, and emits the modulated optical signal to another optical circuit via another part of the grating coupler in the optical communication module. Meanwhile, in the wafer-level automatic inspection, the optical modulator of the chip 30 is supplied with the modulation signal from the inspection device via the cantilever-type probe in contact with the inspection pad 20, modulates the optical signal incident from the optical probe via the grating coupler, and supplies the modulated optical signal to the inspection device via another optical probe.

According to the optical semiconductor integrated circuit according to the present embodiment, the inspection pad 20 is arranged in the peripheral portion of the chip, and the semiconductor element constituting the optical circuit (photodiodes, laser diodes, optical modulators, and the like) is arranged in a center part of the chip, in order to reduce the size of the chip 30. In the case where the present embodiment is applied to the semiconductor integrated circuit not including the optical circuit instead of the optical semiconductor integrated circuit, semiconductor elements (a transistor constituting an amplifier, a driver IC, and the like) constituting an electronic circuit is arranged in a center part of a chip.

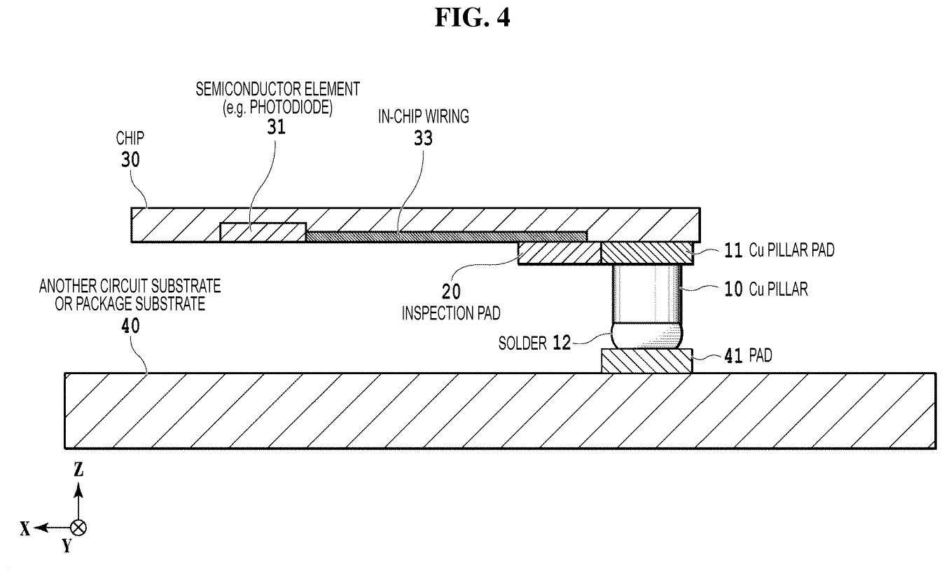

FIG. 4 is a view for describing a state in which the chip 30 is flip-chip mounted on an external package substrate or a circuit substrate 40, using the Cu pillar 10. As illustrated in FIG. 4, a stub (opening) is not generated in a path of an electrical signal between the external circuit substrate 40 and the semiconductor element 31 included in the chip 30.

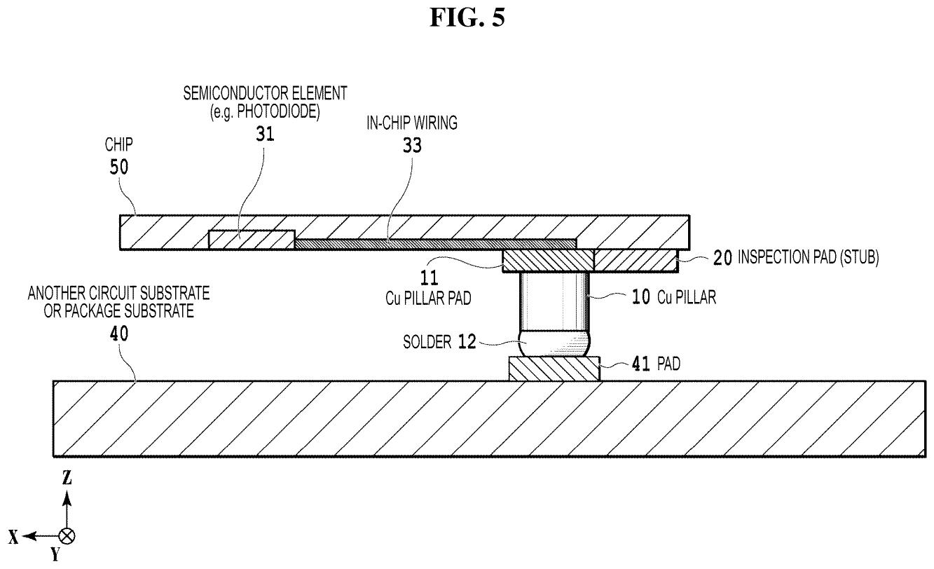

FIG. 5 is a view for describing a state in which a chip 50 obtained by exchanging arrangement of the Cu pillar pad 11 and the inspection pad 20 in the inspection pattern of the chip 30 in FIG. 4 is flip-chip mounted on the external circuit substrate 40. The inspection pad 20 arranged at a position closer to the end surface than the Cu pillar pad 11 acts as a stub, which causes deterioration of high-frequency characteristics.

Since no stub is generated in the optical semiconductor integrated circuit according to the present embodiment, it is possible to perform the wafer-level automatic inspection by arranging the inspection pad 20 and using the low-cost cantilever-type probe card without impairing the high-frequency characteristics.

### Third Embodiment

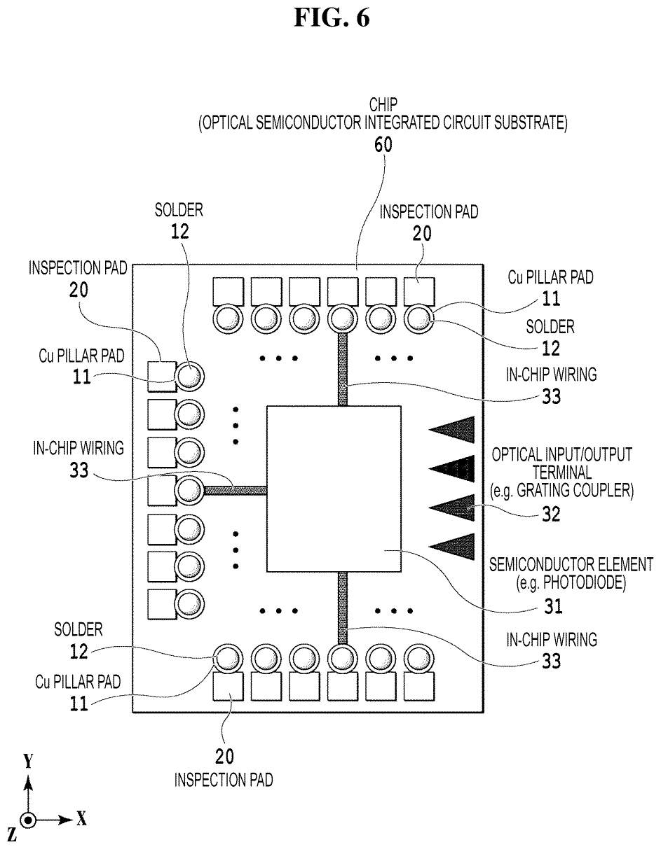

An optical semiconductor integrated circuit according to a third embodiment of the present disclosure will be described with reference to FIG. 6. FIG. 6 illustrates one of a plurality of optical semiconductor integrated circuits formed on a wafer, similarly to FIG. 3. Also in the optical semiconductor integrated circuit according to the present embodiment, an inspection pad 20 is arranged in a peripheral portion of a chip in order to reduce a size of a chip 60, similarly to the above-described optical semiconductor integrated circuit. The rectangular chip 60 illustrated in FIG. 6 is different from the chip 30 illustrated in FIG. 3 in arrangement of a plurality of inspection patterns formed on the chip 60. More specifically, as illustrated in FIG. 6, the chip 60 is different from the chip 30 illustrated in FIG. 3 in that the inspection pad 20 of each inspection pattern is arranged at a position closer to an end surface than a Cu pillar pad 11, and the Cu pillar pad 11 arranged adjacent to the inspection pad 20 is electrically connected to a semiconductor element 31 by in-chip wiring 33.

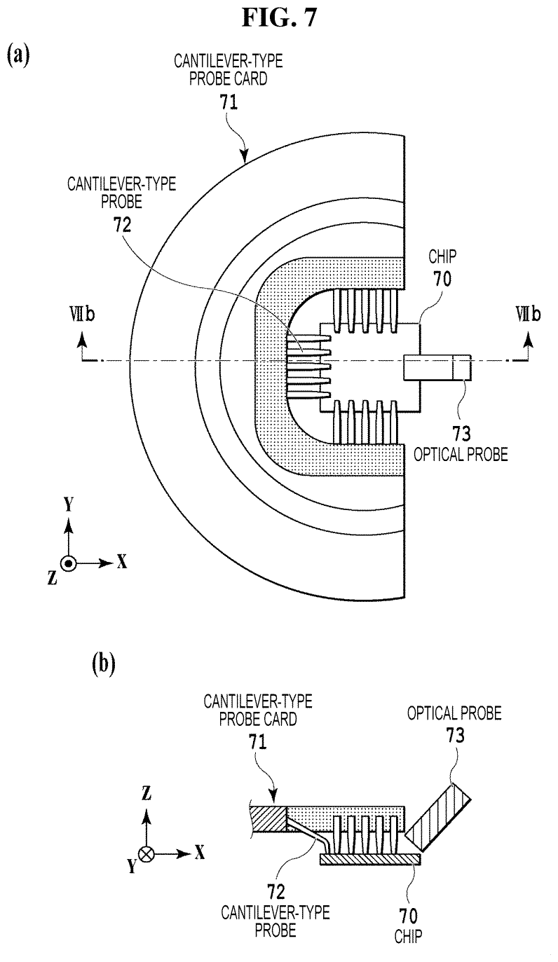

FIG. 7 is views illustrating a cantilever-type probe card and a chip during wafer-level automatic inspection, in which FIG. 7(a) is a top view and FIG. 7(b) is a side view. A cantilever-type probe card 71 illustrated in FIG. 7 has an opening larger than the size of a chip 70 to be inspected, and a cantilever-type probe 72 is arranged around the opening. FIG. 7 also illustrates an optical probe 73 for inspecting input and output of light to and from the chip 70 to be inspected. As illustrated in FIG. 7, in a case of performing the wafer-level automatic inspection using the cantilever-type probe card, the cantilever-type probe 72 enters a peripheral portion of the chip 70 from a chip outer peripheral side toward a chip inner side and comes into contact with the inspection pad. The cantilever-type probe card is cleaned after the inspection is completed. This cleaning involves scraping of a needle tip of the cantilever-type probe.

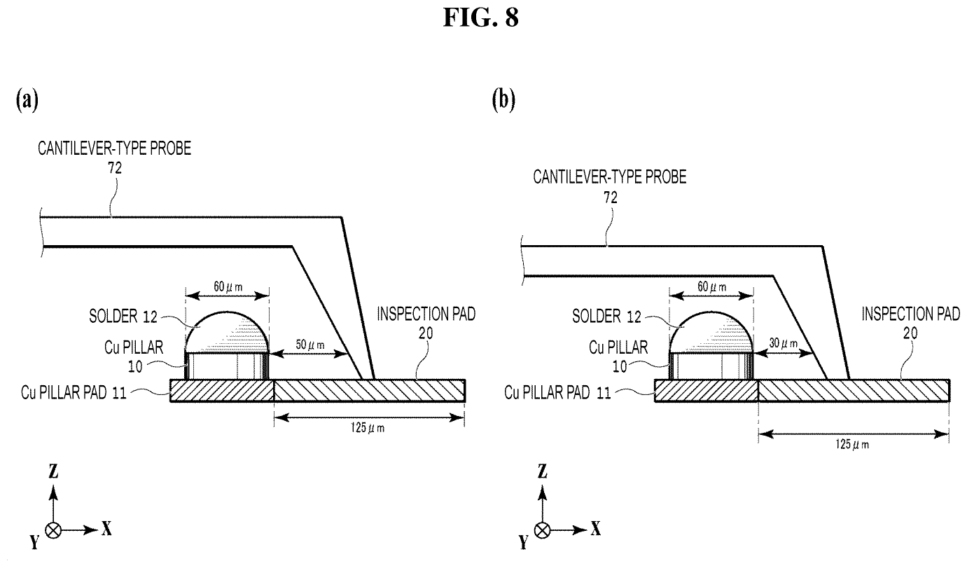

FIG. 8 is views illustrating states in which the needle tip of the cantilever-type probe is in contact with the inspection pad 20 in the inspection pattern of the present disclosure, in which FIG. 8(a) is a view illustrating the cantilever-type probe in which the needle tip is less (newer) scraped and FIG. 8(b) is a view illustrating the cantilever-type probe in which the needle tip is more scraped. As illustrated in FIG. 8(b), in the case where much of the needle tip is scraped by cleaning, the cantilever-type probe 72 approaches a Cu pillar 10 (and solder 12) at the time of wafer-level automatic inspection. If the cantilever-type probe 72 collides with the Cu pillar 10 (and the solder 12), damage is caused. To prevent the collision, it is necessary to increase the size of the inspection pad 20 in advance in consideration of a margin due to scraping of the needle tip. For example, a diameter of a general Cu pillar is 60 μm, and when manufacturing errors of the cantilever-type probe and probing accuracy of an inspection device are also included in the consideration, the Cu pillar 10 and the cantilever-type probe 72 need to be separated from each other by about 30 μm even after cleaning operation. Then, the initial size of the inspection pad 20 needs to be about 125 μm in a direction in which the cantilever-type probe 72 skates.

Meanwhile, according to the optical semiconductor integrated circuit according to the embodiment illustrated in FIG. 6, since the inspection pad 20 is arranged at the position closer to the end surface of the chip 60 than the Cu pillar pad 11, even if the needle tip of the cantilever-type probe 72 is scraped by cleaning, the probe does not approach the Cu pillar 10 (and the solder 12). Therefore, the length in the direction in which the cantilever-type probe 72 having the size of the inspection pad 20 skates can eliminate the margin due to scraping of the needle tip of 20 μm. That is, the inspection pad 20 having the smaller size than the example described above with reference to FIG. 8 can be realized. As a result, by reducing a capacitance component of the inspection pad 20, it is possible to provide an optical semiconductor integrated circuit or a semiconductor integrated circuit capable of arranging the inspection pad 20 and performing inspection using the low-cost cantilever-type probe card 71 without impairing high frequency characteristics.

### Fourth Embodiment

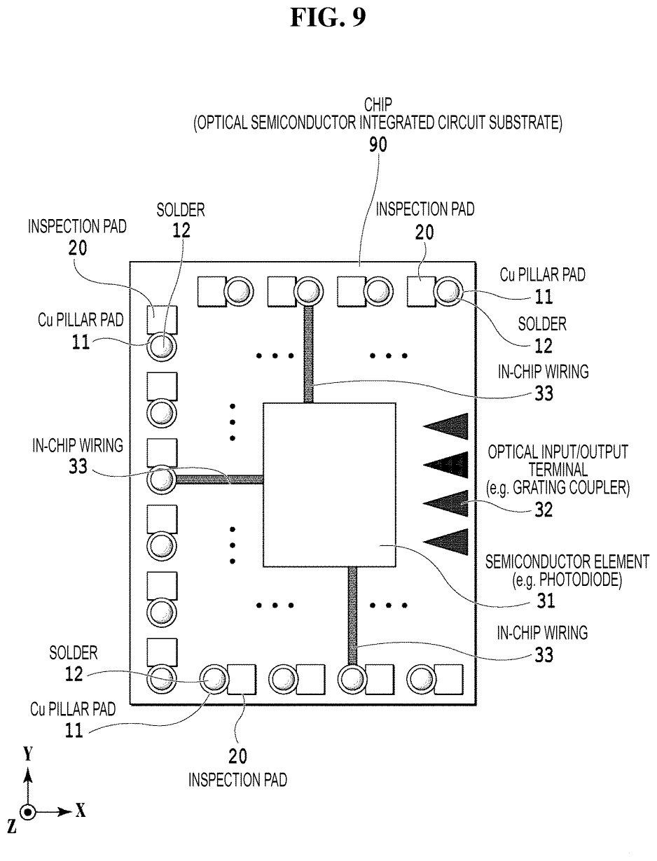

An optical semiconductor integrated circuit according to a fourth embodiment of the present disclosure will be described with reference to FIG. 9. FIG. 9 illustrates one of a plurality of optical semiconductor integrated circuits formed on a wafer, similarly to FIG. 3. Also in the optical semiconductor integrated circuit according to the present embodiment, an inspection pad 20 is arranged in a peripheral portion of a chip in order to reduce a size of a chip 90, similarly to the above-described optical semiconductor integrated circuit. The rectangular chip 90 illustrated in FIG. 9 is different from the chip 30 illustrated in FIG. 3 in arrangement of a plurality of inspection patterns formed on the chip 90. More specifically, as illustrated in FIG. 9, the chip 90 is different from the chip 30 illustrated in FIG. 3 in that the inspection pad 20 and a Cu pillar pad 11 of each inspection pattern are arranged in parallel to a closest end surface, and the Cu pillar pad 11 arranged adjacent to the inspection pad 20 is electrically connected to a semiconductor element 31 by an in-chip wiring 33.

The optical semiconductor integrated circuit according to the present embodiment does not approach a Cu pillar 10 (and solder 12) either even if a needle tip of a cantilever-type probe 72 is scraped by cleaning, similarly to the optical semiconductor integrated circuit according to the embodiment illustrated in FIG. 6. That is, the inspection pad 20 having the smaller size than the example described above with reference to FIG. 8 can be realized. As a result, by reducing a capacitance component of the inspection pad 20, it is possible to provide an optical semiconductor integrated circuit or a semiconductor integrated circuit capable of arranging the inspection pad 20 and performing inspection using a low-cost cantilever-type probe card 71 without impairing high frequency characteristics.

### Fifth Embodiment

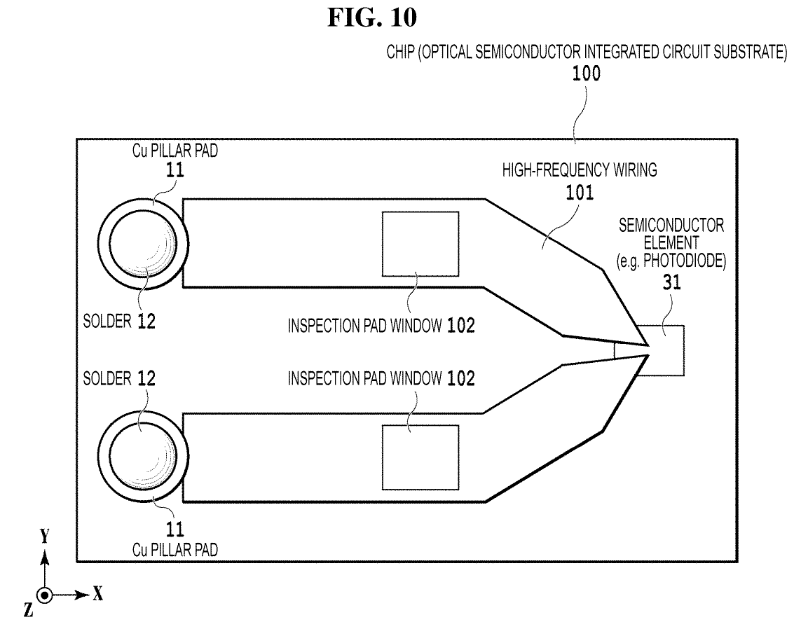

An optical semiconductor integrated circuit according to a fifth embodiment of the present disclosure will be described with reference to FIG. 10. FIG. 10 illustrates one of a plurality of optical semiconductor integrated circuits formed on a wafer, similarly to FIG. 3. The optical semiconductor integrated circuit illustrated in FIG. 10 includes a rectangular chip 100 (that is, an optical semiconductor integrated circuit substrate), a semiconductor element 31 formed on a principal plane (XY plane) of the chip 100, a plurality of inspection patterns, and high-frequency wiring 101 electrically connecting each of the plurality of inspection patterns and the semiconductor element 31. The two pieces of high-frequency wiring 101 in FIG. 10 are examples, and the number of pieces of high-frequency wiring 101 included in the optical semiconductor integrated circuit, that is, the number of inspection patterns is not limited to two. Assuming that a signal line and a ground line are S and G, respectively, the optical semiconductor integrated circuit can include the number of pieces of high-frequency wiring 101 according to a desired configuration such as an SGS configuration or a GSGSG configuration.

The inspection pattern in the optical semiconductor integrated circuit according to the present embodiment includes a Cu pillar pad 11, a Cu pillar 10, solder 12, and an inspection pad window 102. The pattern for inspection is different from that described with reference to FIG. 2 in that in-chip wiring 33 connecting the Cu pillar pad 11 and the semiconductor element 31 is configured as the high-frequency wiring 101, and the inspection pad window 102 is provided on the high-frequency wiring 101. The inspection pad window 102 is a portion excluding a passivation film formed on an upper surface of the chip 100. The inspection pad window 102 has a rectangular shape similarly to the inspection pad 20. The inspection pad window 102 corresponds to the above-described inspection pad 20, and provides a region that a cantilever-type probe arranged on a cantilever-type probe card comes in contact with during wafer-level automatic inspection.

In the optical semiconductor integrated circuit according to the present embodiment, the inspection pad window 102 of each inspection pattern is arranged at a position in a direction away from an end surface closest to the Cu pillar pad 11 (a direction toward an end surface facing the closest end surface).

According to the inspection pattern in the optical semiconductor integrated circuit of the present embodiment, by sufficiently setting a distance between the Cu pillar 10 (and the solder 12) and the inspection pad window 102, it is possible to eliminate a problem of damage due to collision between the Cu pillar 10 and a cantilever-type probe 72. Further, it is not necessary to separately provide an inspection pad 20. Therefore, it is possible to provide an optical semiconductor integrated circuit or a semiconductor integrated circuit capable of performing wafer-level automatic inspection using the inspection pad window 102 and a low-cost cantilever-type probe card, which eliminates an increase in capacitance due to attachment of the inspection pad and degradation of the high frequency characteristics associated therewith.

### Sixth Embodiment

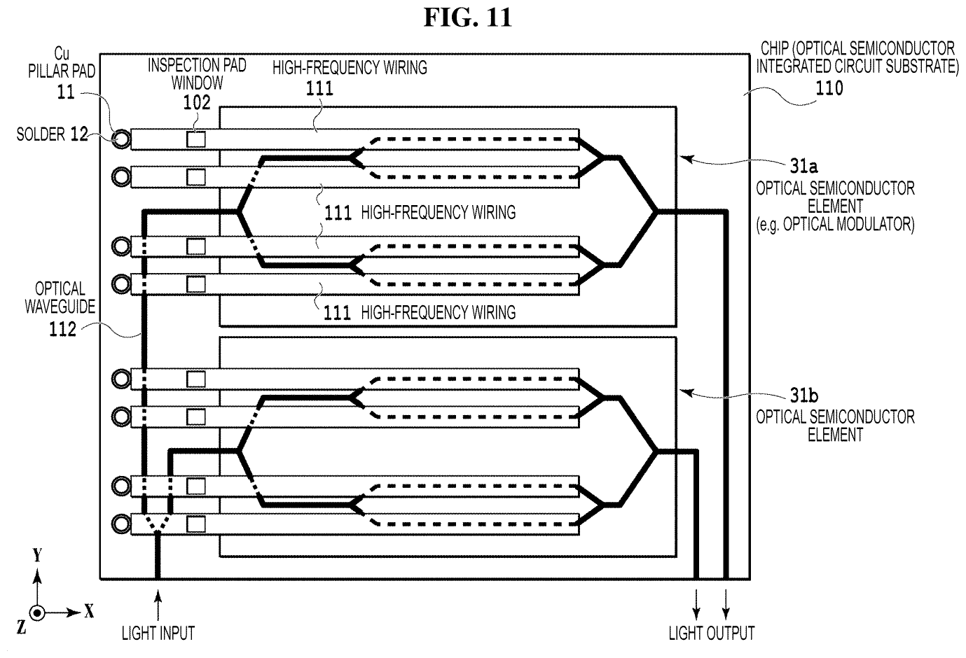

An optical semiconductor integrated circuit according to a sixth embodiment of the present disclosure will be described with reference to FIG. 11. FIG. 11 illustrates one of a plurality of optical semiconductor integrated circuits formed on a wafer, similarly to FIG. 3. The optical semiconductor integrated circuit illustrated in FIG. 11 includes a rectangular chip 110 (that is, an optical semiconductor integrated circuit substrate), two semiconductor elements 31a and 31b formed on a principal plane (XY plane) of the chip 110, a plurality of inspection patterns, and high-frequency wiring 111 electrically connecting each of the plurality of inspection patterns and the semiconductor elements 31a and 31b. As described above with reference to FIG. 10, also in the chip 110 of FIG. 11, the number of pieces of high-frequency wiring 111 is an example, and the number of pieces of high-frequency wiring 111 according to a desired configuration such as an SGS configuration or a GSGSG configuration can be included.

The semiconductor element 31a has a configuration in which a child Mach-Zehnder is arranged in each of two arm optical waveguides constituting one parent Mach-Zehnder. The configuration of the semiconductor element 31b is similar to the configuration of the semiconductor element 31a. The two semiconductor elements 31a and 31b are arranged in parallel, and are configured such that one branched light from input light is modulated by the semiconductor element 31a and the other light is modulated by the semiconductor element 31b. An optical waveguide 112 illustrated in FIG. 11 is a waveguide path through which the input light is modulated and output.

The inspection pattern in the optical semiconductor integrated circuit according to the present embodiment includes a Cu pillar pad 11, a Cu pillar 10, solder 12, and an inspection pad window 102, similarly to the inspection pattern in FIG. 10. In-chip wiring 33 connecting the Cu pillar pad 11 and the semiconductor element 31 is configured as the high-frequency wiring 111, and the inspection pad window 102 is provided on the high-frequency wiring 111. Meanwhile, the inspection pattern in the optical semiconductor integrated circuit according to the present embodiment is different from the inspection pattern described with reference to FIG. 10 in that the optical waveguide 112 intersecting with the high-frequency wiring 111 is formed under the high-frequency wiring 111 between the Cu pillar pad 11 and the inspection pad window 102.

Generally, the optical waveguide occupies a lot of space of the chip. In addition, since there are electrical elements (transistors) and optical semiconductor elements (optical modulators and photodiodes) inside the chip, it may be difficult to secure a space for the optical waveguide. Therefore, in the present embodiment, the optical waveguide 112 is arranged on an outer peripheral portion of the chip 110 in order to reduce the area of the chip 110.

In addition, when the Cu pillar 10 is arranged on the optical waveguide 112, strain stress generated in the Cu pillar 10 after flip-chip mounting affects wavelength characteristics of the optical waveguide 112, and may also affect performance of the optical circuit. In addition, even in a case where the optical waveguide is located below the inspection pad 20, stress by the cantilever-type probe at the time of wafer-level automatic inspection may damage the optical waveguide 112 and affect characteristics such as an increase in loss characteristics. For these reasons, the optical waveguide 112 cannot be arranged below the Cu pillar 10 and below the inspection pad 20.

Therefore, in the chip 110 of the present embodiment, the optical waveguide 112 is arranged on the outer peripheral portion of the chip 110 except for a lower layer of a portion to which the stress is applied (for example, the Cu pillar 10, the inspection pad 20, and the inspection pad window 102). As described above, according to the embodiment of the present application, it is possible to provide an optical semiconductor integrated circuit or a semiconductor integrated circuit capable of wafer-level automatic inspection using an inspection pad and a low-cost cantilever-type probe card while preventing deterioration in characteristics of an optical waveguide or performance of an optical circuit and reducing the size of the chip 110.

### INDUSTRIAL APPLICABILITY

According to the present disclosure, it is possible to provide an optical semiconductor integrated circuit or a semiconductor integrated circuit capable of performing wafer-level automatic inspection using a low-cost cantilever-type probe card.

### REFERENCE SIGNS LIST

10 Cu pillar
11 Cu pillar pad
12 Solder
20 Inspection pad
30, 50, 60, 70, 90, 100, 110 Chip (optical semiconductor integrated substrate)
31 Semiconductor element (Photodiode, optical modulator)
32 Optical input/output terminal (grating coupler)
33 In-chip wiring
40 External circuit (or package substrate)
41 Pad
71 Cantilever-type probe card
72 Cantilever-type probe
73 Optical probe
101, 111 High-frequency wiring
102 Inspection pad window
112 Optical waveguide

1. An inspection pattern comprising:
a Cu pillar pad formed on a semiconductor integrated substrate;
a Cu pillar formed on the Cu pillar pad; and
an inspection pad formed on the semiconductor integrated substrate, electrically coupled adjacent to or proximate to the Cu pillar pad, and configured to provide a region that a cantilever-type probe comes in contact with during wafer-level automatic inspection.

2. The inspection pattern according to claim 1, wherein
the inspection pattern is arranged near an outer periphery of the semiconductor integrated substrate, and
the Cu pillar pad is arranged at a position closer to the outer periphery of the semiconductor integrated substrate than the inspection pad.

3. The inspection pattern according to claim 1, wherein
the inspection pattern is arranged near an outer periphery of the semiconductor integrated substrate, and
the inspection pad is arranged at a position closer to the outer periphery of the semiconductor integrated substrate than the Cu pillar pad.

4. The inspection pattern according to claim 1, wherein
the inspection pattern is arranged near an outer periphery of the semiconductor integrated substrate, and
the inspection pad electrically coupled adjacent to or proximate to the Cu pillar pad and the Cu pillar pad is arranged parallel to the outer periphery of the semiconductor integrated substrate.

5. The inspection pattern according to claim 1, wherein
the inspection pattern is arranged near an outer periphery of the semiconductor integrated substrate, and
the inspection pad is formed on high-frequency wiring formed on the semiconductor integrated substrate, and the high-frequency wiring couples the Cu pillar pad and a semiconductor element and propagates a high-frequency electrical signal between the Cu pillar and the semiconductor element.

6. The inspection pattern according to claim 5, further comprising:
an optical waveguide formed between the Cu pillar pad and the inspection pad, wherein
the high-frequency wiring between the Cu pillar pad and the inspection pad intersects with the optical waveguide.

7. A semiconductor integrated circuit comprising:
the inspection pattern according to claim 1; and
a semiconductor element formed on the semiconductor integrated substrate.

8. An optical semiconductor integrated circuit comprising:
the inspection pattern according to claim 1; and
an optical semiconductor element including an optical circuit formed on the semiconductor integrated substrate.
